(19) United States
(12) Patent Application Publication
(10) Pub. No.: US 2025/0338534 A1
(43) Pub. Date: Oct. 30, 2025

(54) FERROELECTRIC QUATERNARY III-NITRIDE ALLOY-BASED DEVICES

(71) Applicant: The Regents of the University of Michigan, Ann Arbor, MI (US)

(72) Inventors: Samuel Yang, Ann Arbor, MI (US); Ding Wang, Ann Arbor, MI (US); Zetian Mi, Ann Arbor, MI (US)

(21) Appl. No.: 19/193,229

(22) Filed: Apr. 29, 2025

Related U.S. Application Data
(60) Provisional application No. 63/640,178, filed on Apr. 29, 2024.

(51) Int. Cl. H10D 30/47; H10D 30/01; H10D 62/815

(52) U.S. Cl. CPC H10D 30/4732; H10D 30/015; H10D 30/475; H10D 62/8164

(57) ABSTRACT

A device includes a substrate and a heterostructure supported by the substrate. The heterostructure includes a III-nitride layer and a ferroelectric layer supported by the III-nitride layer. The ferroelectric layer includes a quaternary III-nitride alloy. The quaternary III-nitride alloy includes a Group IIIB element. The ferroelectric layer has a lattice constant greater than a lattice constant of gallium nitride (GaN).

### CROSS-REFERENCE TO RELATED APPLICATION

This application claims the benefit of U.S. provisional application entitled “Ferroelectric Quaternary III-Nitride Alloy-Based Devices,” filed Apr. 29, 2024, and assigned Ser. No. 63/640,178, the entire disclosure of which is hereby expressly incorporated by reference.

### STATEMENT REGARDING FEDERALLY SPONSORED RESEARCH OR DEVELOPMENT

This invention was made with government support under Contract No. 2235377 awarded by the National Science Foundation. The government has certain rights in the invention.

### BACKGROUND OF THE DISCLOSURE

### Field of the Disclosure

The disclosure relates generally to ferroelectric Group III-nitride materials.

### Brief Description of Related Technology

Wurtzite nitride ferroelectrics have garnered much attention since their experimental advent in 2019, with significant effort focused on the realization and characterization of ferroelectric ScₓAl₁₋ₓN via sputter deposition. Since then, advances in molecular beam epitaxy (MBE) have led to the demonstration of high-quality monocrystalline ScₓAl₁₋ₓN and ScₓGa₁₋ₓN films with robust ferroelectricity. These materials have been shown to offer larger remanent polarizations and coercive fields and greater scalability, potentially into monolayer regimes, compared with conventional oxide ferroelectrics. Sc incorporation into conventional III-nitrides (e.g., AlN and GaN) has also been shown to greatly enhance their piezoelectric properties. Moreover, ScₓAl₁₋ₓN has been demonstrated to be optically active, and predictions have shown that ScₓGa₁₋ₓN retains a direct bandgap up to x of about 0.5.

### SUMMARY OF THE DISCLOSURE

In accordance with one aspect of the disclosure, a device includes a substrate and a heterostructure supported by the substrate, the heterostructure including a III-nitride layer and a ferroelectric layer supported by the III-nitride layer. The ferroelectric layer includes a quaternary III-nitride alloy. The quaternary III-nitride alloy includes a Group IIIB element. The ferroelectric layer has a lattice constant greater than a lattice constant of gallium nitride (GaN).

In accordance with another aspect of the disclosure, a device includes a substrate and a heterostructure supported by the substrate, the heterostructure including a ferroelectric base layer including a first III-nitride alloy and a ferroelectric cap layer supported by the ferroelectric base layer, the ferroelectric cap layer including a second III-nitride alloy. The first III-nitride alloy includes scandium. The second III-nitride alloy includes gallium.

In accordance with yet another aspect of the disclosure, a device includes a substrate and a heterostructure supported by the substrate, the heterostructure including a multiple quantum well or short-period superlattice structure. The multiple quantum well or short-period superlattice structure includes a stack of alternating barrier layers and quantum well layers. Each barrier layer of the stack includes a quaternary III-nitride alloy. The quaternary III-nitride alloy includes a Group IIIB element. Each quantum well layer of the stack includes a III-nitride layer.

In accordance with still yet another aspect of the disclosure, a method of fabricating a device includes growing a first ferroelectric layer supported by a substrate, the first ferroelectric layer including a first III-nitride alloy, and growing a second ferroelectric layer supported by the ferroelectric base layer, the second ferroelectric layer including a second III-nitride alloy. The second ferroelectric layer includes a quaternary III-nitride alloy. The quaternary III-nitride alloy includes a Group IIIB element. The second ferroelectric layer has a lattice constant greater than a lattice constant of gallium nitride (GaN).

In accordance with still yet another aspect of the disclosure, a method of fabricating a device includes growing a first ferroelectric layer supported by a substrate, the first ferroelectric layer including a first III-nitride alloy, and growing a second ferroelectric layer supported by the ferroelectric base layer, the second ferroelectric layer including a second III-nitride alloy. The first III-nitride alloy includes scandium. The second III-nitride alloy includes gallium.

In connection with any one of the aforementioned aspects, the devices and/or methods described herein may alternatively or additionally include or involve any combination of one or more of the following aspects or features. The ferroelectric layer is in contact with the III-nitride layer. The III-nitride layer has a lattice constant greater than the lattice constant of GaN. The III-nitride layer is doped with a Group IIIB element. The III-nitride layer includes scandium. The quaternary III-nitride alloy includes gallium. The ferroelectric layer has an energy bandgap greater than an energy bandgap of GaN. The III-nitride layer includes a ternary alloy. The III-nitride layer and the ferroelectric layer are lattice-matched. The III-nitride layer is ferroelectric. The device further includes an electrode supported by the ferroelectric layer. The ferroelectric layer is configured as a cap layer for the III-nitride layer in an active area of the device. The electrode is disposed in the active area. The heterostructure includes a multiple quantum well or short-period superlattice structure. The multiple quantum well or short-period superlattice structure includes a stack of quantum well layers and barrier layers. The III-nitride layer is one of the quantum well layers. The ferroelectric layer is one of the barrier layers. The quantum well layers include AlGaN. The quantum well layers and the barrier layers are lattice matched to one another. The quantum well layers and the barrier layers are configured such that the multiple quantum well or short-period superlattice structure has intersubband transitions at a mid-infrared frequency or a far-infrared frequency. The second III-nitride alloy is a quaternary III-nitride alloy. The ferroelectric cap layer is patterned such that a layout of the ferroelectric cap layer corresponds with an active area of the device. The device further includes an electrode supported by the ferroelectric cap layer and disposed in the active area. The ferroelectric base layer and the ferroelectric cap layer are in contact with one another. Each barrier layer is ferroelectric. The barrier layers and the quantum well layers are lattice matched to one another. The method further includes forming an electrode in an active area of the device, the electrode being supported by the ferroelectric cap layer.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts (a) [112̅0] and [101̅0] azimuth RHEED patterns following growth of an example Sc_{0.2}Al_{0.45}Ga_{0.35}N film, (b) a 5 μm×5 μm AFM scan of the surface of the Sc_{0.2}Al_{0.45}Ga_{0.35}N film, giving a rms roughness of about 0.5 nm, in which the scale bar represents 1 μm, (c) a (0002) plane XRD 2θ-ω scan results showing Sc_{0.2}Al_{0.45}Ga_{0.35}N, with a FWHM of about 0.34°, and Sc_{0.2}Al_{0.8}N, and (d) an elemental distribution map of an example capacitor structure via EDX, in which the scale bar represents 20 nm.

FIG. 2 depicts graphical plots of (a) a representative P-E loop for an example Sc_{0.2}Al_{0.45}Ga_{0.35}N film, unambiguously showing hysteresis due to ferroelectricity. (b) a bipolar C-V loop and extracted loss tangent, in which C-V hysteresis further confirms ferroelectric switching, (c) a PUND transient obtained with 0.05 ms rectangular pulses (blue), demonstrating switching and non-switching current components (red), and (d) electric field dependent PUND measurements, revealing clear polarization saturation.

FIG. 3 depicts graphical plots of (a) dependence of polarization reversal on the width and electric field of an applied writing pulse, showing experimental data (symbols) and fitting results obtained from the KAI model (solid curves), and (b) extracted fitting parameters from the KAI model, demonstrating n of about 2 and a nearly linear relationship between log (to) and electric field across the evaluation range.

FIG. 4 depicts PFM amplitude and phase images, obtained over a 5 μm×5 μm scan area, of an example Sc_{0.2}Al_{0.45}Ga_{0.35}N layer poled to opposite polarizations corresponding to normalized values of (a) 0 (pristine), (b) 0.3, (c) 0.6, (d) 0.8, and (e) 1 (fully reversed), in which the corresponding writing pulse widths for parts (b)-(e) are 10 μs, 25 μs, 35 μs, and 70 μs, respectively, to evidence the nucleation and growth of polarity inversion domains, and in which the scale bars represent 1 μm.

FIG. 5 is a schematic, cross-sectional view of a ferroelectric field effect transistor (FeFET) memory cell with a ferroelectric, single-crystal (monocrystalline) layer of a quaternary III-nitride alloy (e.g., ScAlGaN) between a gate electrode and a source-drain conduction region in accordance with one example.

FIG. 6 is a flow diagram of a method of fabricating a heterostructure having an epitaxially grown ferroelectric layer of a quaternary III-nitride alloy in accordance with one example.

FIG. 7 is a schematic, cross-sectional view of a heterostructure having a cap layer of a quaternary III-nitride alloy (e.g., ScAlGaN) in accordance with one example.

FIG. 8 is a schematic, cross-sectional view of a device having a superlattice with layers of a quaternary III-nitride alloy (e.g., ScAlGaN) in accordance with one example.

FIG. 9 is a schematic, cross-sectional view of a micro-ring resonator modulator (MRMs) and a magnified ring resonator having a superlattice with ferroelectric layers of a quaternary III-nitride alloy (e.g., ScAlGaN) in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices and heterostructures with one or more layers of a quaternary III-nitride alloy (e.g., ScAlGaN) are described. In some cases, the layers may be ferroelectric. As described herein, the quaternary III-nitride alloy provides an additional degree of material tunability. For instance, ranges of material parameters such as bandgap, band alignment, lattice parameter, and piezoelectric constant may be realized through the quaternary alloys described herein. Methods for fabricating such devices are also described.

The tunability of material parameters such as bandgap, band alignment, lattice parameter, and piezoelectric constant, are useful for electronic, optoelectronic, and acoustic devices. The materials ScₓAl₁₋ₓN and ScₓGa₁₋ₓN offer some tunability through the adjustment of Sc compositions. However, films with high Sc compositions often suffer from degraded material quality, accompanied by significant increases in leakage currents and degeneration of desirable ferroelectric and piezoelectric properties. As described herein, the quaternary alloy ScₓAl_{y}Ga_{1-x-y}N may be used to bridge the tunability gap between ScₓAl₁₋ₓN and ScₓGa₁₋ₓN. The material quality of ScₓAl₁₋ₓN may also be improved by incorporating Ga into ScₓAl₁₋ₓN, thus forming ScₓAl_{y}Ga_{1-x-y}N.

The layers of ScₓAl_{y}Ga_{1-x-y}N may also be ferroelectric. Examples of ferroelectricity in ScₓAl_{y}Ga_{1-x-y}N grown on Mo via plasma-assisted MBE are described herein, along with details regarding ferroelectric switching behavior. For instance, examples of monocrystalline Sc_{0.2}Al_{0.45}Ga_{0.35}N with readily acquired ferroelectricity were investigated systematically through a diverse array of characterization techniques, revealing a coercive field of about 5.5 MV cm⁻¹ and high remanent polarization of about 150 μC cm⁻². Furthermore, the examples establish that polarization reversal in ScₓAl_{y}Ga_{1-x-y}N follows a scheme of domain nucleation and growth, which is confirmed through piezoresponse force microscopy (PFM). The availability of ferroelectric ScₓAl_{y}Ga_{1-x-y}N supports the fabrication of wurtzite nitride-based heterostructures for a vast variety of devices and systems.

Example heterostructures including a layer of ScₓAl_{y}Ga_{1-x-y}N on Mo were grown using a Veeco GENxplor MBE system. Active nitrogen species with 6N purity was provided through a Veeco radio frequency UNI-Bulb plasma source. Aluminum (6N5 purity), gallium (7N purity), and scandium (99.99% purity) were supplied using Knudsen effusion cells. The employed template included 40 nm Mo on 20 nm Sc₂O₃ on silicon (111). 90 nm of ScₓAl_{y}Ga_{1-x-y}N was then grown under moderately nitrogen rich conditions. The alloy content was tunable by adjusting the Al and Ga beam equivalent pressures, with the composition determined by energy dispersive x-ray spectroscopy (EDX). In these examples, Sc_{0.2}Al_{0.45}Ga_{0.35}N was chosen to ensure a crack-free film with good surface morphology, offering greater stability in characterization and minimizing the formation of leakage current paths. The corresponding beam equivalent pressures were about 2.2×10⁻⁸ torr for Sc, 4.5×10⁻⁸ torr for Al, and 4.5×10⁻⁸ torr for Ga. The epitaxial process was monitored using an in-situ reflection high energy electron diffraction (RHEED) system. Following growth, the surface morphology was characterized ex-situ using a Bruker Dimension Icon atomic force microscope (AFM). A Rigaku SmartLab x-ray diffractometer (XRD) with a Cu Kα source (wavelength of 1.5406 Å) was used to characterize the XRD pattern of the grown samples. A Thermo Fisher Scientific Talos F200X STEM equipped with Super-X EDX was used to measure the sample thickness and composition and to perform elemental distribution mapping. Circular contact pads with diameters 10-150 μm, serving as drive electrodes, included 20 nm Ti followed by 150 nm Al, and were patterned on the ScₓAl_{y}Ga_{1-x-y}N film via standard photolithography, with the underlying Mo layer serving as the bottom electrode, thereby forming example capacitors. All electrical and ferroelectric measurements were performed with a B1500 semiconductor analyzer and a Radiant Precision Multiferroic II system at room temperature. To explore the domain evolution within ScₓAl_{y}Ga_{1-x-y}N during polarity switching, a Burker Icon AFM was applied for PFM. In preparation for PFM, aqueous hydrogen fluoride (HF) was used to remove the electrodes from samples following poling.

Although described in connection with examples of epitaxially grown ScₓAl_{y}Ga_{1-x-y}N layers, the disclosed methods and devices may be applied to a variety of quaternary III-nitride alloys. The disclosed methods and devices may thus include or involve the incorporation of scandium into other III-nitride wurtzite structures. For instance, the disclosed methods and devices may include or involve one or more epitaxially grown ScₓIn_{y}Ga_{1-x-y}N layers. The configuration, construction, fabrication, and other characteristics of the heterostructures may also vary from the examples described. For instance, the heterostructures may include any number of epitaxially grown layers of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although described in connection with examples having compositions of Sc_{0.2}Al_{0.45}Ga_{0.35}N, the compositions of the III-nitride alloys of the disclosed devices and heterostructures may vary. Indeed, varying the compositions may be used for lattice matching and/or other tuning, e.g., as described herein.

Although described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

Further details on the epitaxial growth conditions, procedures, and related parameters that may be used to form the structures and heterostructures described herein are set forth in WO 2023/022768 (“Epitaxial Nitride Ferroelectronics”), International Application No. PCT/US23/13727 (“Epitaxial Nitride Ferroelectronic Devices” filed Feb. 23, 2023), P. Wang, et al., “Fully epitaxial ferroelectric ScAlN grown by molecular beam epitaxy,” Applied Physics Letters, vol. 118, p. 223504 (2021), D. Wang et al., “An Epitaxial Ferroelectric ScAlN/GaN Heterostructure Memory,” Advanced Electronic Materials, p. 2200005 (2022), D. Wang, et al., “Fully epitaxial ferroelectric ScGaN grown on GaN by molecular beam epitaxy,” Appl Phys Lett 119 (11), 111902 (2021), D. Wang et al., “Impact of dislocation density on the ferroelectric properties of ScAlN grown by molecular beam epitaxy,” Appl Phys Lett 121 (4), 042108 (2022), P. Wang et al., “Quaternary alloy ScAlGaN: A promising strategy to improve the quality of ScAlN,” Appl Phys Lett 120 (1), 012104 (2022), and P. Wang et al. “Ferroelectric Nitride Heterostructures on CMOS Compatible Molybdenum for Synaptic Memristors,” ACS Appl. Mater. Interfaces 2023, 15, 14, 18022-18031 (2023), the entire disclosures of which are hereby incorporated by reference.

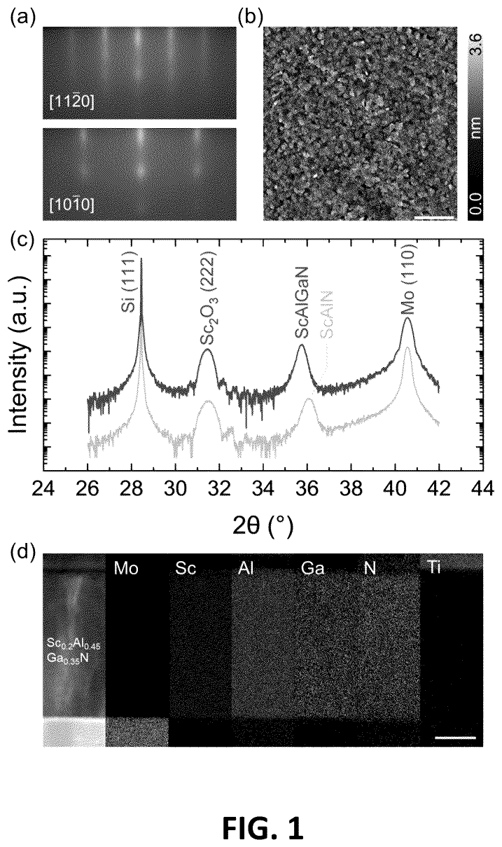

FIG. 1, part (a), shows the RHEED patterns of one example capacitor along the and azimuths, respectively, following the growth of a Sc_{0.2}Al_{0.45}Ga_{0.35}N layer. The RHEED patterns are reasonably streaky, indicating good film quality and smooth surface morphology. The AFM image of FIG. 1, part (b), presents the surface morphology of the film. The rms roughness from the 5 μm×5 μm scan is about 0.5 nm, which confirms the excellent surface morphology. No cracks or undesirable secondary phases are observed on the surface of the film, and the domain-like topography visible in the AFM scan is due to the domains present within the Mo substrate. FIG. 1, part (c), shows the (0002) plane XRD 2θ-ω scan results for the Sc_{0.2}Al_{0.45}Ga_{0.35}N layer, along with the corresponding XRD scan for a Sc_{0.2}Al_{0.8}N layer. Both scans exhibit a characteristic diffraction peak corresponding to the wurtzite structure. It is observed that the incorporation of Ga into ScₓAl₁₋ₓN results in the signature diffraction peak shifting towards lower angles, indicating an increase of the out-of-plane lattice parameter c. The Sc_{0.2}Al_{0.45}Ga_{0.35}N peak exhibits a full-width half-maximum (FWHM) of about 0.34°, further corroborating the excellent quality of the film. No other peaks are observed in a long-range scan from 20° to 100°, signifying that no other phases of Sc_{0.2}Al_{0.45}Ga_{0.35}N are present. Due to the difficulty in ascertaining the quaternary composition from XRD scans, EDX in a TEM is used to determine the alloy content and to map the distribution of elements in the film. FIG. 1, part (d), illustrates the element maps of the Al/Ti/SC_{0.2}Al_{0.45}Ga_{0.35}N/Mo capacitor structure, where for clarity purposes, the topmost Al layer is not included in the image. Uniform incorporation of Sc, Al, and Ga can be seen along the growth direction of the film, with no nonhomogeneous clusters formed. The dark layer observed in the HAADF image at the Ti/Sc_{0.2}Al_{0.45}Ga_{0.35}N interface is due to amorphous oxides that form spontaneously upon air exposure.

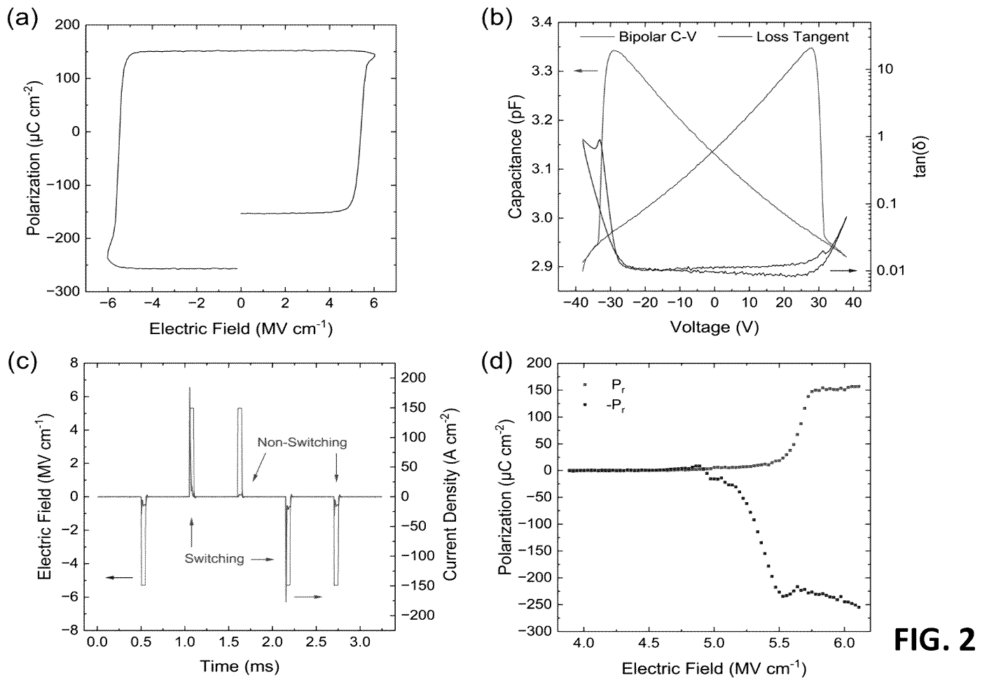

To examine the ferroelectricity of Sc_{0.2}Al_{0.45}Ga_{0.35}N, P-E (polarization versus electric field), C-V (capacitance versus voltage), and PUND (positive-up-negative-down) measurements were carried out on the fabricated example capacitors. Similar to ScₓGa₁₋ₓN grown by MBE, the Sc_{0.2}Al_{0.45}Ga_{0.35}N example exhibited noticeable wake-up behavior. Therefore, all example devices tested were pre-stressed with 100 cycles of a triangular AC waveform to exclude wake-up effects. A representative P-E loop, measured using a triangular waveform input at 10 kHz, is presented in FIG. 2, part (a). The P-E loop demonstrates clear hysteresis indicative of ferroelectricity. The open nature of the P-E loop can be ascribed to asymmetric leakage currents at high electric field. Such behavior has also been previously observed in ScₓAl₁₋ₓN and ScₓGa₁₋ₓN grown by MBE and sputter deposition. A coercive field of about 5.5 MV cm⁻¹ can be extracted from the P-E loops, which is in a similar range as for ScₓAl₁₋ₓN and YₓAl₁₋ₓN with high Al compositions. FIG. 2, part (b), shows the results of C-V measurements of the quaternary film. The butterfly-shaped C-V hysteresis affirms the ferroelectric behavior of the film. Note that the coercive field suggested by the C-V measurements (about 3.1 MV cm⁻¹) is substantially lower than that extracted from P-E loops due to the slow sweep employed during C-V acquisition. The dielectric loss obtained from the C-V measurements remains small for much of the sweep range, with the increase at high biases due to leakage currents at high electric fields.

FIG. 2, part (c), illustrates the PUND transient with a maximum applied electric field of about 5.5 MV cm⁻¹. To limit the contribution of leakage currents while ensuring complete switching, a pulse width of 0.05 ms was used. Current peaks corresponding to ferroelectric polarization switching are evident during the P and N pulses. Non-switching current can be observed during the U and D pulses, due to the non-negligible leakage current. To quantify the remanent polarization, electric field dependent PUND measurements were performed. The results are displayed in FIG. 2, part (d). A modified PUND waveform consisting of two additional U and D pulses each (PUUUNDDD) was applied to minimize the effects of incomplete switching at low and moderate electric fields and to apply leakage current compensation to the measurement. The saturation in polarization for both branches, clear beyond an applied field of about 5.7 MV cm⁻¹, serves as further evidence of ferroelectricity and indicates a large remanent polarization of about 150 μC cm⁻². The asymmetry in the branches, as well as the larger observed polarizations in the negative branch, may be due to leakage currents and the dynamic generation of defects and interfaces, including vacancies and domain walls. Measurements on other example capacitors yielded similar results.

To analyze the ferroelectric switching behavior of Sc_{0.2}Al_{0.45}Ga_{0.35}N, the dependence of polarity reversal on the width of an applied pulse is quantified. Polarization switching within a monocrystalline ferroelectric has been described by Ishibashi et al. in the Kolmogorov-Avrami-Ishibashi (KAI) model: P=1−exp [−(t/t₀)ⁿ], where P is the polarization inversion fraction, to is the characteristic switching time, and n is an exponential factor. Ishibashi et al. proposed that n equals the growth dimensionality of the polarity reversal domains during ferroelectric switching. For thin film ferroelectrics, the KAI model predicts that n=2, where the polarity inversion is achieved through nucleation and subsequent growth of the inversion domains. Other models, such as the nucleation-limited switching (NLS) model, proposed by Tagantsev et al., have been applied to textured PbZrₓTi₁₋ₓO₃ films. However, such films are often polycrystalline and contain grains of various orientations, rendering the KAI model unsuitable. On the other hand, because the wurtzite structure possesses spontaneous polarization only along the c-axis, wurtzite nitride ferroelectrics are limited to 180° domains. As such, the KAI model is considered useful for the monocrystalline ScₓAl_{y}Ga_{1-x-y}N films described herein.

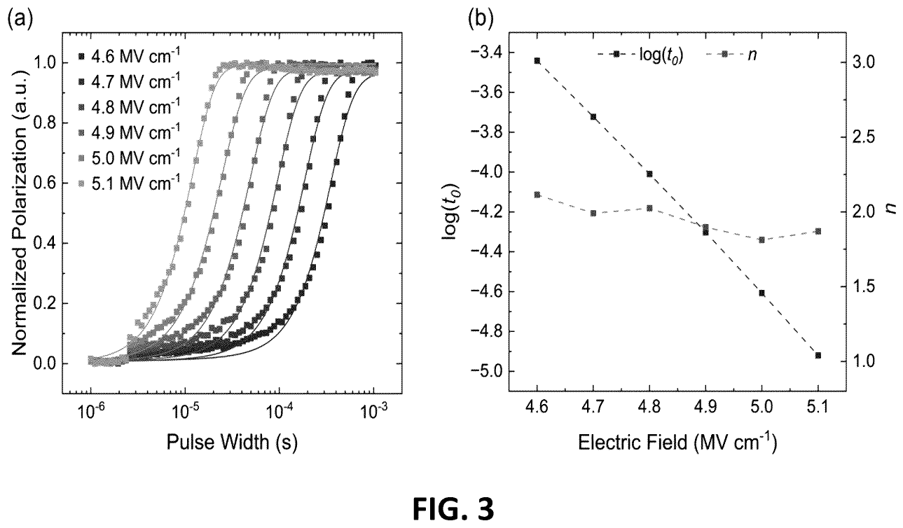

The time dependence of polarization reversal was measured using a pulse sequence consisting of a positive conditioning pulse, a negative writing pulse, and two positive reading pulses. The maximum electric field during the conditioning and reading pulses is set to about 5.5 MV cm⁻¹ to ensure complete switching. FIG. 3, part (a), displays the results of the measurements, normalized to the maximum obtained polarization. Due to the limited temporal resolution and rise time of the measurement setup, writing pulse widths narrower than 1 us and electric fields greater than 5.1 MV cm⁻¹ were not investigated. The experimental results can be reasonably fitted to the KAI model, shown as solid curves in FIG. 3, part (a). The extracted fitting parameters are presented in FIG. 3, part (b). The exponential parameter n is about 2 across all examined electric fields, which is in good agreement with the suggestion that the growth of polarity reversal domains occurs via an in-plane motion of the domain walls. Furthermore, log (to) clearly decreases as the applied electric field increases, indicating an increase in polarization reversal propagation speed with electric field, which is in good agreement with previous studies performed on ScₓAl₁₋ₓN. Notably, the dependence of log (to) on electric field does not appear to saturate as the applied field increases. Combined with the consistency of n about 2 across the measurement series, the results indicate that the mechanism through which the polarity reversal domains evolve does not change significantly with increasing field.

The evolution of polarity inversion domains with polarization was investigated via PFM. Following the results in FIG. 3, part (a), several 30 μm diameter capacitors were poled to pre-determined polarizations by adjusting the width of a 5 MV cm⁻¹ negative poling pulse. To replicate the writing process previously used as closely as possible, each capacitor was pre-stressed accordingly and conditioned with a positive pulse of about 5.5 MV cm⁻¹ prior to being poled with the negative pulse. The electrodes were then removed using HF to expose the Sc_{0.2}Al_{0.45}Ga_{0.35}N film for PFM, with HF treatment resulting in only a minor increase of surface roughness.

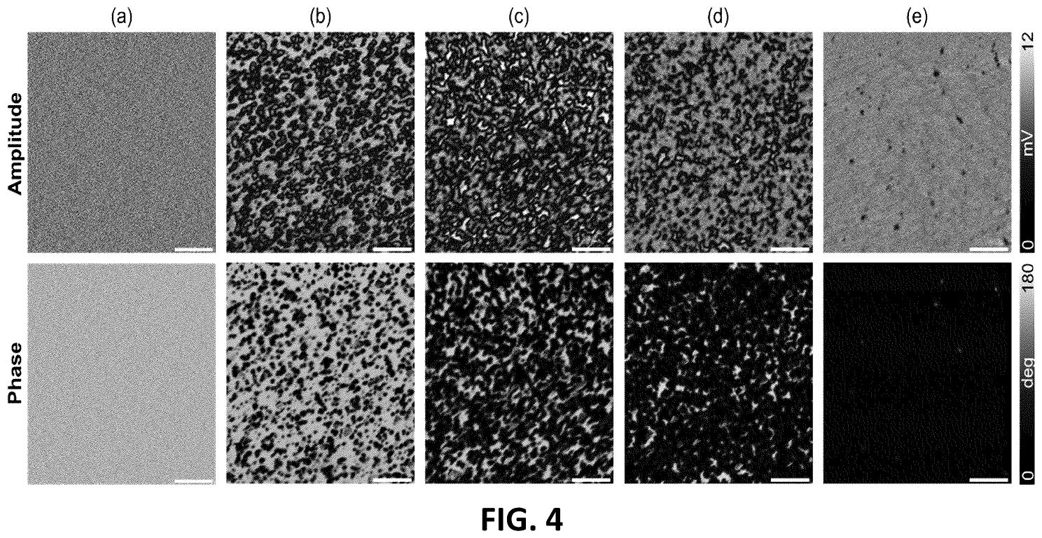

FIG. 4, parts (a)-(e), show 5 μm×5 μm PFM amplitude and phase images for polarizations corresponding to normalized values of 0 (pristine), 0.3, 0.6, 0.8, and 1 (fully reversed). Within the PFM phase images, the light color (or shading) corresponds to regions with the same polarity as the pristine film, while the dark color (or shading) corresponds to regions with inverted polarity. The image contrast is verified by poling two capacitors with negative pulses, but fully back-switching one of them with a subsequent positive pulse. Evident in FIG. 4, part (b), small dark spots can be seen throughout the phase image, corresponding to nucleated domains. At this stage, these domains remain largely separate and distinct. As shown in FIG. 4, parts (c)-(d), the domains clearly grow and begin coalescing with increasing polarization reversal. Eventually, the polarity of the entire area is reversed, demonstrated in FIG. 4, part (e), apart from a few minor spots, possibly due to crystal defects. Additionally, within FIG. 4, parts (b)-(d), the phase difference between the regions of opposing polarities is 180°, which corresponds with the expectation that nitride ferroelectrics possess 180° domains. These results not only support the domain nucleation and growth mechanism proposed by the KAI model, but also physically elucidate the evolution of polarity reversal domains in wurtzite nitride ferroelectrics.

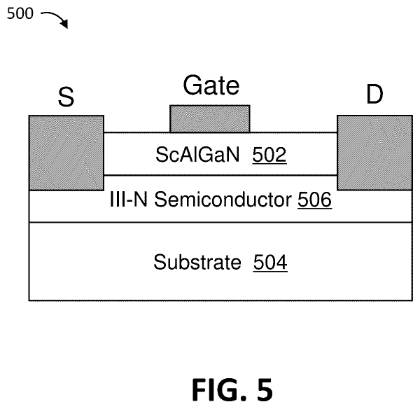

FIG. 5 depicts a device 500 having a heterostructure with a quaternary ferroelectric layer 502 in accordance with one example. In this example, the device 500 is configured as a field effect transistor device, such as a high electron mobility transistor (HEMT) device. The device 500 includes a substrate 504, such as sapphire, but alternative or additional materials may be used. The heterostructure is supported by the substrate 504. In some cases, the heterostructure is in contact with the substrate 504.

The heterostructure includes a III-nitride layer 506 and the ferroelectric layer 502 supported by the III-nitride layer 506. In this example, the ferroelectric layer 502 includes a quaternary III-nitride alloy. The quaternary III-nitride alloy includes a Group IIIB element, such as Sc, but alternative or additional Group IIIB elements may be used. The ferroelectric layer 502 may be in contact with the III-nitride layer 506 as shown.

In this example, the ferroelectric layer 502 has a lattice constant greater than a lattice constant of gallium nitride (GaN). The composition of the quaternary III-nitride alloy may be configured to realize a desired lattice constant. For instance, the desired lattice constant may correspond with a lattice constant of the underlying III-nitride layer 506. In some cases, the III-nitride layer 506 has a lattice constant greater than the lattice constant of GaN. For instance, the III-nitride layer 506 may be composed of AlGaN. In such cases, the quaternary III-nitride alloy may be configured to be lattice-matched to AlGaN. Achieving such lattice matching would be challenging with III-nitride alloys, such as ScAlN, without sacrifices in, e.g., material quality due to undesirably high Sc content. Lattice matching to other III-nitride alloys may also be achieved, including, for instance, InGaN.

The lattice matching made possible by the quaternary III-nitride alloy may be used to realize heterostructures (e.g., superlattice structures) that allow various electronic, optical, and/or non-linear optical properties to be achieved without worrying about lattice mismatch. For instance, the heterostructures may be configured to offer a tunable energy bandgap while still maintaining lattice matched layers.

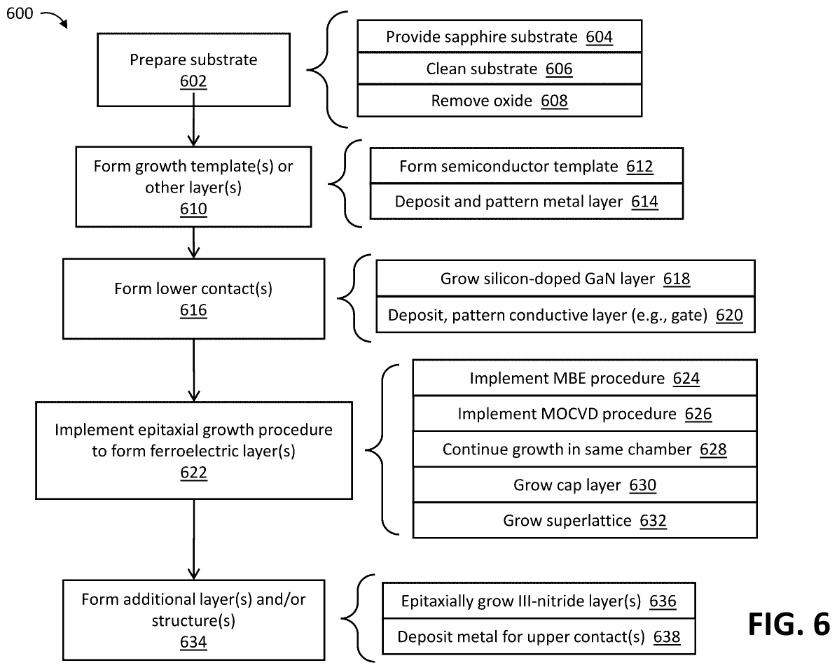

FIG. 6 depicts a method 600 of fabricating a heterostructure having one or more III-nitride alloy layers in accordance with one example. As described herein, the method 600 is configured such that one or more of the III-nitride alloy layers exhibits ferroelectric behavior. The heterostructure may form a device, or a part of a device, in which one or more layers or regions of the device exhibit the ferroelectric behavior. The method 600 may be used to fabricate the examples described herein and/or other examples.

The method 600 may begin with an act 602 in which a substrate is prepared and/or otherwise provided. In some cases, the act 602 includes providing a sapphire substrate in an act 604. Alternative or additional materials may be used, including, for instance, silicon, bulk GaN, bulk AlN, or other semiconductor material. Still other materials may be used, including, for instance, silicon carbide. The substrate may be cleaned in an act 606. In some cases, a native or other oxide layer may be removed from a substrate surface in an act 608. Additional or alternative processing may be implemented in other cases, including, for instance, doping or deposition procedures. The substrate thus may or may not have a uniform composition. The substrate may be a uniform or composite structure.

In an act 610, one or more growth templates or other layers are formed. The layer(s) are thus formed on, or otherwise supported by, the substrate. The layer(s) may or may not be in contact with the substrate. In some cases, the layer(s) are composed of, or otherwise include, a semiconductor material. For instance, the act 610 may include an act 612 in which a semiconductor layer is formed. For example, a III-nitride layer, such as a GaN layer, may be grown or otherwise formed on the substrate. Other compound or other semiconductor materials may be used, including, for instance, AlN or AlGaN. The act 612 may thus be implemented before (e.g., in preparation for) implementing an epitaxial growth procedure in which a wurtzite structure is formed. The ferroelectric layer(s) may thus be formed on the semiconductor layer. The semiconductor layer may be configured or used as a growth template for the ferroelectric layer(s) and/or other elements of the heterostructure. In some cases, the act 612 may include growing the semiconductor layer in an epitaxial growth chamber in which the epitaxial growth procedure for the ferroelectric layer(s) is implemented. As a result, the substrate may remain within, e.g., is not removed from, the epitaxial growth chamber between forming the semiconductor layer and implementing the epitaxial growth procedure for growing the ferroelectric layer(s).

Alternatively or additionally, the act 610 includes an act 614 in which one or more metal or other conductive layers are deposited and patterned. For example, an aluminum layer may be deposited on a silicon substrate in preparation for the epitaxial growth of the ferroelectric layer(s).

The method 600 may include an act 616 in which one or more contacts are formed. In the example of FIG. 6, the contact(s) are configured as a lower or bottom contact of the heterostructure. In some cases, the act 616 includes growing a silicon-doped GaN layer in an act 618. Additional or alternative conductive structures, such as a gate structure, may be deposited and/or patterned in an act 620.

In an act 622, a non-sputtered epitaxial growth procedure is implemented to form ferroelectric layer(s) supported by the substrate. As described herein, one of the ferroelectric layer(s) may composed of, or otherwise includes, a quaternary III-nitride alloy. For instance, the alloy may be ScAlGaN. Additional or alternative quaternary III-nitride materials may be grown, including, for instance, ScInGaN. As also described herein, the epitaxial growth procedure is configured to incorporate scandium and/or another group IIIB element into the alloy of the III-nitride material. In some cases, the act 622 includes an act 624 in which an MBE procedure is implemented. In other cases, an MOCVD or other non-sputtered epitaxial growth procedure is implemented in an act 626.

The act 622 may constitute a continuation, or part of a sequence, of growth procedures. The growth procedures may be implemented in a common, or same, growth chamber. The act 622 may thus include an act 628 in which epitaxial growth is continued in the same chamber. Sequential layers of the heterostructure may thus be grown without exposure to the ambient. The quality of the interface between the layers may accordingly be improved.

The growth temperature may be at a level such that the ferroelectric layer exhibits a breakdown field strength greater than a ferroelectric coercive field strength of the material. Ferroelectric switching and other behavior may thus be achieved. Growth of a single crystal of the scandium-including alloy (e.g., a monocrystalline layer of the alloy) is also achieved. For example, in some cases, a quaternary III-nitride alloy may be epitaxially grown at a growth temperature of about 600 degrees Celsius or less. The quaternary III-nitride alloy may be grown at other growth temperatures, e.g., as described herein. In some cases, a nitrogen-to-metal flux ratio higher than 1 may be used.

The growth temperature may correspond with the temperature measured at a thermocouple in the growth chamber. The growth temperature at the epitaxial surface may be slightly different. The growth temperature is accordingly approximated via the temperature measurement at the thermocouple.

At each level within the range of suitable growth temperatures, the resulting wurtzite structure is monocrystalline. The resulting wurtzite structure is monocrystalline to a degree not realizable via, for instance, sputtering-based procedures for forming the III-nitride alloy layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

The above-noted differences in crystal quality evidenced via x-ray diffraction rocking curve line widths may also be used to distinguish between monocrystalline and polycrystalline structures. As used herein, the term “polycrystalline” refers to structures having x-ray diffraction rocking curve line widths on the order of a few degrees or higher. As used herein, the term “monocrystalline” refers to structures having x-ray diffraction rocking curve line widths at least one order of magnitude lower than the order of a few degrees.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

In some cases, the act 622 includes the growth of multiple ferroelectric layers. For instance, the act 622 may include an act 630 in which a ferroelectric base layer and a ferroelectric cap layer are grown. The ferroelectric cap layer may be used to prevent oxidation of the ferroelectric base layer without sacrificing the ferroelectric (or piezoelectric) functionality of the ferroelectric base layer.

The multiple ferroelectric layers may be configured to form the alternating stacked layers of a multiple quantum well or short-period superlattice structure. The act 622 may include an act 632 in which the alternating stacked layers are grown.

The method 600 may include an act 634 in which one or more layers (e.g., semiconductor layers) are formed after growth of the wurtzite structure. As a result, the layer(s) may be in contact with the wurtzite structure. For instance, one or more III-nitride (e.g., GaN or AlGaN) or other semiconductor layers may be epitaxially grown in an act 636. The act 636 may be implemented in the same epitaxial growth chamber used to grow the wurtzite structure. As a result, the substrate (and heterostructure) is not removed from the epitaxial growth chamber between implementing the acts 622 and 634.

Alternatively or additionally, the act 634 includes an act 638 in which one or more metal or other conductive layers or structures are formed. The layers or structures may be deposited or otherwise formed. In some cases, the conductive structure is configured as an upper or top contact. For instance, the conductive structure may be a gate.

The method 600 may include one or more additional acts. For example, one or more acts may be directed to forming other structures or regions of the device that includes the heterostructure. In a transistor device example, the regions may correspond with source and drain regions. The nature of the regions or structures may vary in accordance with the nature of the device.

The order of the acts of the method 600 may differ from the example shown in FIG. 6. For example, the acts 616, 618, 620 in which contacts and/or other conductive structures formed may be implemented after the growth of the ferroelectric layer.

A number of different types of devices may be fabricated by the method 600 of FIG. 6, and/or another method of fabricating a heterostructure as described herein. For example, the heretostructures may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

A number of further example devices are now described. In each example, the device includes a substrate and a heterostructure supported by the substrate. The heterostructure includes a III-nitride layer and a ferroelectric layer supported by the III-nitride layer. The ferroelectric layer includes a quaternary III-nitride alloy, and the quaternary III-nitride alloy includes a Group IIIB element, such as Sc, but other Group IIIB elements may be used. In some cases, the III-nitride layer is also ferroelectric.

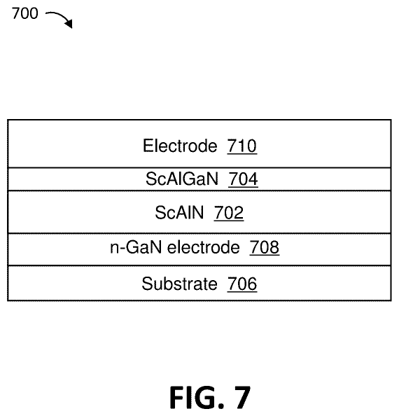

FIG. 7 depicts a device 700 having a heterostructure with multiple ferroelectric layers 702, 704 in accordance with one example. In this example, the device 700 is configured as a capacitor, but the device 700 may have alternative or additional functionality in other cases. The device 700 may have one or more features in common with one of the other devices described herein.

The device 700 includes a substrate 706 and a heterostructure supported by the substrate 706. The substrate 706 may be composed of, or otherwise include, sapphire, but alternative or additional materials may be used. In this example, the heterostructure includes a lower electrode 708 supported by the substrate 706. The lower electrode 708 may be composed of, or otherwise include, n-doped GaN, but alternative or additional materials may be used.

The heterostructure includes a ferroelectric base layer 702 and a ferroelectric cap layer 704 supported by the ferroelectric base layer 702. The ferroelectric base layer 702 and the ferroelectric cap layer 704 may be in contact with one another as shown. The ferroelectric base layer 702 is composed of, or otherwise includes, a first III-nitride alloy. The ferroelectric cap layer 704 is composed of, or otherwise includes, a second III-nitride alloy.

The ferroelectric cap layer 704 may have a composition that prevents or minimizes oxidation. For instance, in cases in which the base layer includes scandium (e.g., ScAlN), the base layer may be highly susceptible to oxidation. To avoid such oxidation while maintaining the ferroelectric nature of the heterostructure, the III-nitride alloy of the ferroelectric cap layer 704 may include gallium. For example, the ferroelectric cap layer 704 may be composed of ScGaN (or other Ga-containing ternary III-nitride alloy) or ScAlGaN (or other Ga-containing quaternary alloy).

The ferroelectric cap layer 704 may be patterned such that a layout of the ferroelectric cap layer 704 corresponds with an active area of the device 700. In this example, the device 700 includes a top electrode 710 supported by the ferroelectric cap layer 702 and disposed in the active area.

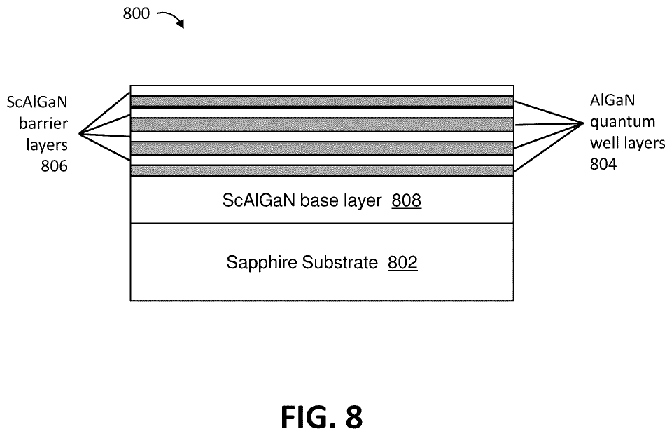

FIG. 8 depicts a device 800 with a heterostructure having a multiple quantum well or short-period superlattice structure in accordance with one example. The device 800 may be configured as an optoelectronic device (e.g., an emitter), a memory device, or another device. The device 800 may have one or more features in common with one of the other devices described herein. For instance, the device 800 may include a sapphire substrate 802, but alternative or additional materials may be used.

The multiple quantum well or short-period superlattice structure includes a stack of quantum well layers 804 and barrier layers 806. In this example, each one of the quantum well layers 804 is a III-nitride layer, such as AlGaN, but alternative or additional III-nitrides may be used. Each one of the barrier layers 806 is composed of, or otherwise includes, a quaternary III-nitride alloy, such as ScAlGaN, but alternative or additional quaternary alloys may be used. In some cases (e.g., in memory devices), the barrier layers 806 may be ferroelectric. In other cases (e.g., intersubband and other optoelectronic devices), the barrier layers 806 are not ferroelectric.

The heterostructure may also include a base layer 808 supported by the substrate 802. The base layer 808 may or may not be composed of, or otherwise includes, the same quaternary III-nitride alloy of the barrier layers 806.

The quaternary III-nitride alloy may have a composition such that the base layer 808, the quantum well layers 804, and the barrier layers 806 are lattice matched to one another.

The quantum well layers 804 and the barrier layers 806 may be configured such that the multiple quantum well or short-period superlattice structure has intersubband transitions at a mid-infrared frequency or a far-infrared frequency.

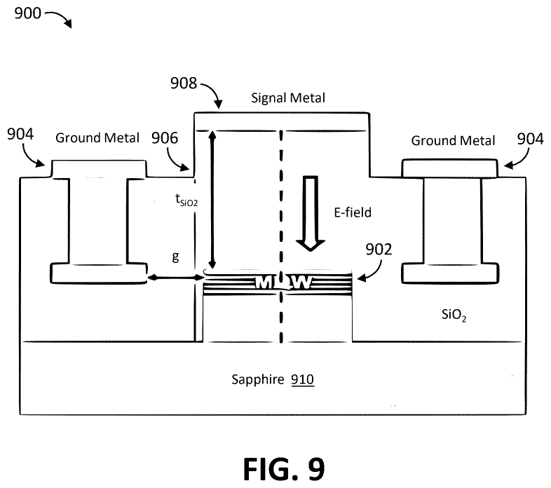

FIG. 9 shows a ring resonator 900 having a heterostructure that includes a multiple quantum well 902 or short-period superlattice structure in accordance with one example. The heterostructure may be configured as described above in connection with FIG. 8. In this example, ground metal electrodes 904 or structures are disposed on or along the lateral sides of a core 906 of the ring resonator 900, and a signal metal electrode 908 or structure is placed on top of the ring resonator 900 above the core 906. The resonator core 906 includes a heterostructure supported by a substrate 910 (e.g., sapphire substrate). The heterostructure, in turn, includes a base layer and the multiple quantum well 902 or short-period superlattice structure supported by the base layer. The base layer may be composed of, or otherwise include, a quaternary III-nitride alloy as described herein. The multiple quantum well 912 or short-period superlattice structure may include a stack of AlN-based quantum well layers (e.g., AlGaN) and quaternary barrier layers as described herein.

Examples of ferroelectric, single-phase high-quality wurtzite quaternary alloy Sc_{0.2}Al_{0.45}Ga_{0.35}N were grown via plasma-assisted molecular beam epitaxy. The example layers or films unambiguously exhibited ferroelectricity with a coercive field of about 5.5 MV cm⁻¹ and large remanent polarization of about 150 μC cm⁻², which are comparable to previous reports on other nitride ferroelectrics. The examples also exhibited a surface roughness of about 0.5 nm, which may be limited or otherwise affected by the surface roughness of an underlying layer (e.g., a Mo template layer). Furthermore, the ferroelectric switching behavior was found to be in good agreement with the KAI model, with piezoresponse force microscopy (PFM) further supporting and elucidating the polarity reversal mechanism of domain nucleation and growth of inversion domains occurring via an in-plane motion of the domain walls. In alternative cases, other quaternary alloys may be formed by introducing a wide range of Sc, Al, Ga, In, and B compositions to fully bridge the gap between the corresponding ternaries (e.g., ScAlN and ScGaN). The III-nitride alloy ferroelectrics described herein may be used in a wide variety of devices and applications, including, for instance, memory devices, reconfigurable electronics and optoelectronics, energy harvesting and storage, MEMS, and piezoelectric devices.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a heterostructure supported by the substrate, the heterostructure comprising:
a III-nitride layer; and
a ferroelectric layer supported by the III-nitride layer;
wherein:
the ferroelectric layer comprises a quaternary III-nitride alloy;
the quaternary III-nitride alloy comprises a Group IIIB element; and
the ferroelectric layer has a lattice constant greater than a lattice constant of gallium nitride (GaN).

2. The device of claim 1, wherein the ferroelectric layer is in contact with the III-nitride layer.

3. The device of claim 1, wherein the III-nitride layer has a lattice constant greater than the lattice constant of GaN.

4. The device of claim 1, wherein the III-nitride layer is doped with a Group IIIB element.

5. The device of claim 4, wherein:
the III-nitride layer comprises scandium; and
the quaternary III-nitride alloy comprises gallium.

6. The device of claim 1, wherein the ferroelectric layer has an energy bandgap greater than an energy bandgap of GaN.

7. The device of claim 1, wherein:
the III-nitride layer comprises a ternary alloy;
the III-nitride layer and the ferroelectric layer are lattice-matched.

8. The device of claim 1, wherein the III-nitride layer is ferroelectric.

9. The device of claim 1, further comprising an electrode supported by the ferroelectric layer, wherein:
the ferroelectric layer is configured as a cap layer for the III-nitride layer in an active area of the device; and
the electrode is disposed in the active area.

10. The device of claim 1, wherein:
the heterostructure comprises a multiple quantum well or short-period superlattice structure;
the multiple quantum well or short-period superlattice structure comprises a stack of quantum well layers and barrier layers;
the III-nitride layer is one of the quantum well layers; and
the ferroelectric layer is one of the barrier layers.

11. The device of claim 10, wherein the quantum well layers comprise AlGaN.

12. The device of claim 10, wherein the quantum well layers and the barrier layers are lattice matched to one another.

13. The device of claim 10, wherein the quantum well layers and the barrier layers are configured such that the multiple quantum well or short-period superlattice structure has intersubband transitions at a mid-infrared frequency or a far-infrared frequency.

14. A device comprising:
a substrate; and
a heterostructure supported by the substrate, the heterostructure comprising:
a ferroelectric base layer comprising a first III-nitride alloy; and
a ferroelectric cap layer supported by the ferroelectric base layer, the ferroelectric cap layer comprising a second III-nitride alloy;
wherein:
the first III-nitride alloy comprises scandium; and
the second III-nitride alloy comprises gallium.

15. The device of claim 14, wherein the second III-nitride alloy is a quaternary III-nitride alloy.

16. The device of claim 14, wherein the ferroelectric cap layer is patterned such that a layout of the ferroelectric cap layer corresponds with an active area of the device.

17. The device of claim 16, further comprising an electrode supported by the ferroelectric cap layer and disposed in the active area.

18. The device of claim 14, wherein the ferroelectric base layer and the ferroelectric cap layer are in contact with one another.

19. A device comprising:
a substrate; and
a heterostructure supported by the substrate, the heterostructure comprising a multiple quantum well or short-period superlattice structure;
wherein:
the multiple quantum well or short-period superlattice structure comprises a stack of alternating barrier layers and quantum well layers;
each barrier layer of the stack comprises a quaternary III-nitride alloy;
the quaternary III-nitride alloy comprises a Group IIIB element; and
each quantum well layer of the stack comprises a III-nitride layer.

20. The device of claim 19, wherein each barrier layer is ferroelectric.

21. The device of claim 19, wherein the barrier layers and the quantum well layers are lattice matched to one another.

22. A method of fabricating a device, the method comprising:
growing a first ferroelectric layer supported by a substrate, the first ferroelectric layer comprising a first III-nitride alloy; and
growing a second ferroelectric layer supported by the ferroelectric base layer, the second ferroelectric layer comprising a second III-nitride alloy;
wherein:
the second ferroelectric layer comprises a quaternary III-nitride alloy;
the quaternary III-nitride alloy comprises a Group IIIB element; and
the second ferroelectric layer has a lattice constant greater than a lattice constant of gallium nitride (GaN).

23. A method of fabricating a device, the method comprising:
growing a first ferroelectric layer supported by a substrate, the first ferroelectric layer comprising a first III-nitride alloy; and
growing a second ferroelectric layer supported by the ferroelectric base layer, the second ferroelectric layer comprising a second III-nitride alloy;
wherein:
the first III-nitride alloy comprises scandium; and
the second III-nitride alloy comprises gallium.

24. The method of claim 23, further comprising forming an electrode in an active area of the device, the electrode being supported by the ferroelectric cap layer.
